(19) United States
(12) Patent Application Publication
(10) Pub. No.: US 2025/0364469 A1
(43) Pub. Date: Nov. 27, 2025

(54) OFFSET PILLARS FOR A MEMORY SYSTEM

(71) Applicant: Micron Technology, Inc., Boise, ID (US)

(72) Inventors: Yen Chun Lee, Boise, ID (US); Raghukiran Sreeramaneni, Purchase, NY (US)

(21) Appl. No.: 19/178,669

(22) Filed: Apr. 14, 2025

Related U.S. Application Data
(60) Provisional application No. 63/645,689, filed on May 10, 2024.

(51) Int. Cl. H01L 23/00; H01L 23/48; H01L 23/528; H01L 25/18; H10B 80/00

(52) U.S. Cl. CPC H01L 24/14; H01L 23/481; H01L 23/5286; H01L 24/16; H01L 25/18; H10B 80/00; H01L 2224/1412; H01L 2224/14519; H01L 2224/16146; H01L 2224/16148; H01L 2225/06513; H01L 2924/30101

(57) ABSTRACT

Methods, systems, and devices for offset pillars for a memory system are described. A memory system may include a memory device consisting of an interface die and one or more memory dies stacked on top of it. The interface die may include power pillars that are coupled with a power supply and configured to route power to each of the stacked dies. The interface die may be larger than the stacked dies (e.g., in a horizontal direction) such that the power pillars are located near the periphery of the stacked dies and are “offset” from the respective power pillars of the stacked dies.

### CROSS REFERENCE

The present application for patent claims priority to U.S. Patent Application No. 63/645,689 by Lee et al., entitled “OFFSET PILLARS FOR A MEMORY SYSTEM,” filed May 10, 2024, which is assigned to the assignee hereof, and which is expressly incorporated by reference in its entirety herein.

### TECHNICAL FIELD

The following relates to one or more systems for memory, including offset pillars for a memory system.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports offset pillars for a memory system in accordance with examples as disclosed herein.

FIGS. 2A and 2B show examples of an architecture that support offset pillars for a memory system in accordance with examples as disclosed herein.

FIG. 3 shows an example of an architecture that supports offset pillars for a memory system in accordance with examples as disclosed herein.

FIG. 4 shows an example of an architecture that supports offset pillars for a memory system in accordance with examples as disclosed herein.

### DETAILED DESCRIPTION

Some memory devices may include one or more dies in a stacked configuration. For example, high bandwidth memory (HBM) devices may include an interface die coupled with a power supply and may include one or more dies (e.g., core dies, second dies, third dies, etc.) stacked on top of the interface die. The stacked dies may include respective memory arrays (e.g., memory banks, DRAM banks) and the interface die may include circuitry (e.g., complementary metal-oxide semiconductor (CMOS) circuitry) for accessing the respective memory arrays. In some instances, the dies may be coupled with respective pillars that can route power between the dies (e.g., power pillars) or provide a thermal barrier between the dies (e.g., thermal dies).

Conventional stacked memory devices may route power between the dies using a power spine that extends from the interface die to a topmost stacked die in a single vertical plane. Due to the configuration of the power spine, there are few eligible locations on the memory device that the power spine can be located. Thus, such power spines are often located near the middle of the dies (e.g., in a horizontal direction), thus requiring power to travel vertically (e.g., up from the interface die) and horizontally (e.g., outward from the power spine) in order to power the components of a respective memory die. Accordingly, determining a location to place a power spine adds complexity to the design of the memory device, and the additional distance for the power to travel (e.g., in the horizontal direction) may reduce the device's overall performance. The resistance in the conductive paths of the power network may influence how much power is consumed by the memory device. Thus, a memory device having a reduced resistance in its power network may be desirable.

A stacked memory device having additional power pillars at the interface die is described herein. In some examples, a memory system may include a memory device that includes an interface die having one or more memory dies stacked on top of it. The interface die may be coupled with a plurality of power pillars that are each coupled with a first stacked memory die (e.g., a first memory die). Some of the plurality of power pillars that are coupled with the interface die may be within the power spine, while others may be outside of the power spine, but still connected with the power delivery network. Having multiple power pillar connections between the interface die and the first stacked memory die may reduce the resistance in the power delivery network and improve the performance of the memory system. The power pillars may be connected to (e.g., coupled with) a power supply and may provide power to each of the dies stacked on the interface die. The power pillars may route the power using respective power pillars that are “offset” from each other (e.g., in a vertical direction). That is, the configuration of the interface die may allow for multiple vias (e.g., through-silicon vias (TSVs)) to extend from the power pillars and connect to the power supply.

These additional power connection points may provide power to the stacked dies in a more uniform manner, which may improve the memory device's overall performance. Moreover, because the interface die may be larger (e.g., in the horizontal direction) than the dies stacked on top of it, the additional power pillars may be relatively close to the periphery of the stacked dies, without increasing the overall size of the memory device. Accordingly, implementing the offset pillars described herein may increase the quantity of power connection points of a memory device and increase its overall performance without increasing its size.

In addition to applicability in memory systems as described herein, offset pillars for a memory system may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by providing additional power connections at or near the periphery of the memory device, which may decrease processing or latency times, improve response times, or otherwise improve user experience, among other benefits.

Features of the disclosure are illustrated and described in the context of systems and architectures. Features of the disclosure are further illustrated and described in the context of various architectures that support offset pillars for a memory system.

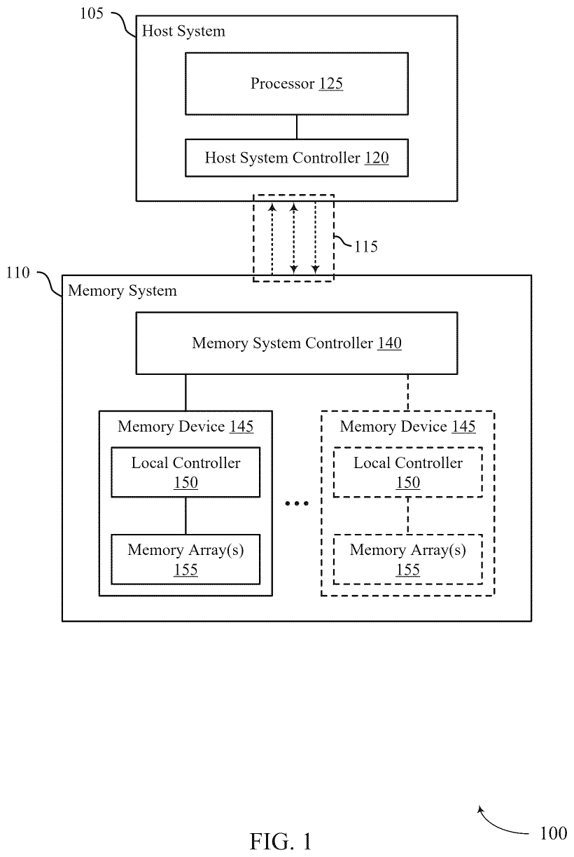

FIG. 1 illustrates an example of a system 100 that supports offset pillars for a memory system in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

A stacked memory device 145 having additional power pillars at the interface die is described herein. In some examples, a memory system 110 may include a memory device 145 that includes an interface die having one or more memory dies stacked on top of it. The interface die may be coupled with a plurality of power pillars that are each coupled with a first stacked memory die (e.g., a first memory die). Some of the plurality of power pillars that are coupled with the interface die may be within the power spine, while others may be outside of the power spine, but still connected with the power delivery network. Having multiple power pillar connections between the interface die and the first stacked memory die may reduce the resistance in the power delivery network and improve the performance of the memory system 110. The power pillars may be connected to (e.g., coupled with) a power supply and may provide power to each of the dies stacked on the interface die. The power pillars may route the power using respective power pillars that are “offset” from each other (e.g., in a vertical direction). That is, the configuration of the interface die may allow for multiple vias (e.g., through-silicon vias (TSVs)) to extend from the power pillars and connect to the power supply. Accordingly, implementing the offset pillars described herein may increase the quantity of power connection points of a memory device 145 and increase the overall performance of the memory system 110 without increasing its size.

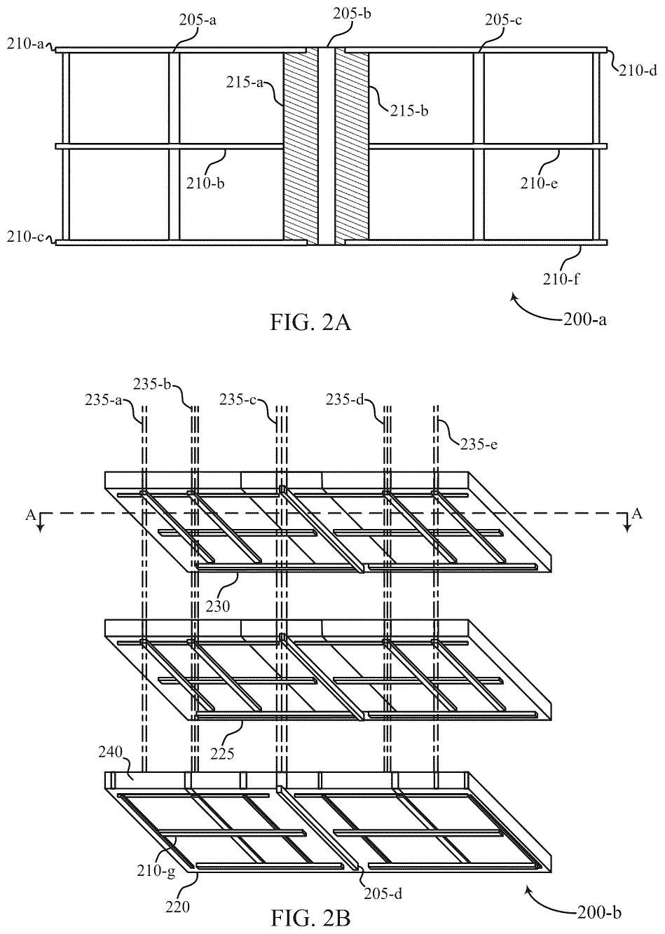

FIG. 2A shows an example of an architecture 200-a that supports offset pillars for a memory system in accordance with examples as disclosed herein. The architecture 200-a may illustrate a top-down view of aspects of a stacked memory device. In some instances, the architecture 200-a may illustrate one or more power spines 205 and one or more rails 210 (e.g., one or more power rails 210). The architecture 200-a may illustrate one or more stacked dies (e.g., an interface die and one or more memory dies stacked on top), and the power spines 205 and the rails 210 may route power from a power supply to each die. In some instances, the power spines 205 and the rails 210 may route power from one or more power pillars as described herein. Implementing the offset pillars described herein may increase the quantity of power connection points of a memory device and increase the overall performance of the associated memory system without increasing its size.

In some instances, a memory device may include one or more power spines. As used herein, a power spine may refer to one or more coplanar power pillars that are coupled with respective dies and are configured to route power (e.g., to the respective dies) from a power source up through the stack of memory dies. An interface die be positioned at the bottom of the stack of memory dies. The interface die may be coupled with a relatively larger quantity of power pillars than a conventional memory system, which may improve the uniformity of power delivery to stacked dies, among other benefits. That is, an interface die may be coupled with multiple power pillars (e.g., some power pillars inside the power spine and some power pillars outside of the power spine), which may otherwise be or be referred to as conductive pillars, that serve as connection points to a power source, and each of the connection points (e.g., each of the power pillars of the interface die) may be coupled with one or more power spines that extend up the stack of dies. Thus, the power pillars coupled with the interface die may route power to the stacked dies using the power spine(s), and the power spine(s) may route power to each of the stacked dies using the power spines and rails. Because the interface die may be coupled with multiple power pillars, the resistance of the power delivery network may be reduced, which may improve the performance of the memory device.

The memory device may include one or more power spines 205 and one or more rails 210. As used herein, a power spine 205 may refer to a region or a structure coupled a power source. Additionally, or alternatively, a rail 210 may refer to a wiring structure, a power rail, or another structure configured to receive a power signal from one or more of the power spines 205. For example, a power source may provide power to a power spine 205 (e.g., via the power pillars coupled with the interface die) and the power spine 205 may route the power signal to the stacked dies in a vertical direction (e.g., up the stack of dies). Each power spine 205 and each rail 210 may receive the power signal, and may route the power signal across a respective die (e.g., outward from the power spines 205, in a horizontal direction). As described herein, the presence and location of the power pillars coupled with the interface die may improve the uniformity of power delivery to the dies via the respective power spines 205 and rails 210.

In some examples, the memory device may include one or more I/O regions 215. The I/O regions 215 may each include one or more pads (e.g., I/O pads) associated with the respective memory arrays. For example, a memory array located on a stacked die may receive and transmit signaling via one or more I/O pads of a respective I/O region 215. Implementing the offset pillars described herein may increase the quantity of power connection points of a memory device and increase the overall performance of the associated memory system without increasing its size.

FIG. 2B shows an example of an architecture 200-b that supports offset pillars for a memory system in accordance with examples as disclosed herein. The architecture 200-b may illustrate aspects of an interface die 220, a first memory die 225, and a second memory die 230. In some instances, the architecture 200-b may illustrate one or more power spines 205 and one or more rails 210. The architecture 200-b may also illustrate one or more power spines 235 and a power rail 240 coupled with the interface die 220. For example, FIG. 2B may be an exploded isometric view of the architecture 200-a illustrated in FIG. 2A. In some instances, the power spines 205 and rails 210 may route power received from one or more power pillars (e.g., via the power spines 235). Implementing the offset pillars described herein may increase the quantity of power connection points of a memory device and increase the overall performance of the associated memory system without increasing its size.

In some instances, a memory device may include one or more power spines 205 and 235. As used herein, a power spine 205 and 235 may refer to one or more coplanar power pillars that are coupled with respective dies and are configured to route power (e.g., to the respective dies) from a power source. The power spines 205 and 235 may be coupled with one or more power pillars of the interface die 220 as described herein. In some instances, the power pillars may not be coplanar with the power spines 235. Rather, the power pillars may be “offset,” thus power may be routed from a power source to the first memory die 225 and the second memory die 230 via a non-linear path. Additionally or alternatively, a power spine 205 may refer to a power spine extending in a first direction (e.g., a horizontal direction) and a power spine 235 may refer to a power spine extending in a second direction (e.g., a vertical direction). In some instances, the term “power spine” may refer to a combination of a power spine 205 and a power spine 235.

As described with reference to FIG. 2A, a power source may provide power to a power spine 235 (e.g., via the power pillars coupled with the interface die 220) and the power spine 235 may route the power signal to the first memory die 225 and the second memory die 230 in a vertical direction (e.g., up the stack of dies). Each memory die may include respective power spines 205 and rails 210, and may receive the power signal from the power spine(s) 235 and may route the power signal across a respective die (e.g., outward from the power spine(s), in a horizontal direction). As described herein, the presence and location of the power pillars coupled with the interface die 220 may improve the uniformity of power delivery to the dies via the respective power spines 205 and rails 210.

In some instances, the interface die 220 may include a power rail 240 (e.g., a fourth power rail, a backside redistribution layer (BS-RDL)). The power rail 240 may be coupled with one or more power spines 235. That is, the power spines 235 may be coupled with a power source via the one or more power pillars of the interface die 220, and may also be coupled with the power rail 240. Thus, the power spines 235 may route a power signal (e.g., a first power signal) to the first memory die 225 and the second memory die 230 from the power source, and may also route a power signal (e.g., a second power signal) to the first memory die 225 and the second memory die 230 from the power rail 240. As described herein, the power spines 205 and the rails 210 may route the power signals to the respective memory dies. By connecting the power spines 235 to the power rail 240, additional voltage (e.g., an increased voltage) may be provided to the first memory die 225 and the second memory die 230.

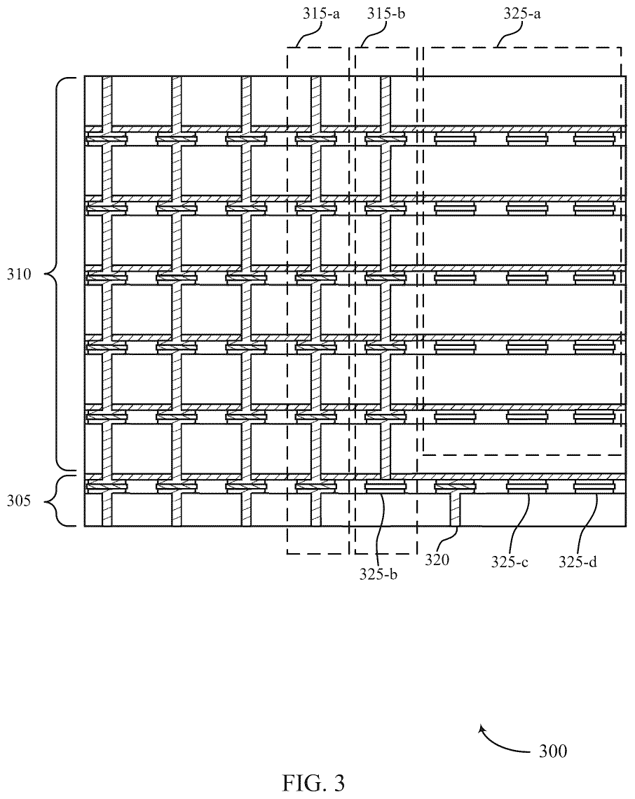

FIG. 3 shows an example of an architecture 300 that supports offset pillars for a memory system in accordance with examples as disclosed herein. The architecture 300 may illustrate a side view of aspects of a stacked memory device. In some instances, the architecture 300 may illustrate an interface die 305 and one or more stacked dies 310 above (e.g., on top of) the interface die 305. The interface die 305 may be coupled with a power source (not shown). In some instances, the interface die 305 and the stacked dies 310 may include or otherwise be coupled with one or more power spines 315, one or more power pillars 320, and one or more thermal pillars 325. In some instances, the power spines 315 and power pillars 320 may route power from the interface die 305 to each of the stacked dies 310. Additionally, or alternatively, the thermal pillars 325 may provide insulative benefits to the interface die 305, the stacked dies 310, or both. Implementing the offset pillars described herein may increase the quantity of power connection points of a memory device and increase the overall performance of the associated memory system without increasing its size.

As described herein, a power spine 315 may refer to one or more coplanar power pillars that are coupled with respective dies and are configured to route power (e.g., to the respective dies) from a power source. For example, the power spine 315-a may extend through the interface die 305 and N stacked memory dies 310. Thus, the power spine 315-a may include N+1 power pillars. Additionally, or alternatively, the power spine 315-b may extend through N stacked memory dies 310. That is, the power spine 315-b may not extend through the interface die 305, and thus may include N power pillars.

In some instances, the power pillar 320 may be coupled with a power source for the associated memory device. As described herein, the interface die 305 may be coupled with a relatively larger quantity of power pillars than a conventional memory system, which may improve the uniformity of power delivery to stacked dies 310, among other benefits. That is, the interface die 305 may be coupled with multiple power pillars 320 that serve as connection points to a power source. The power pillar 320 may, for example, route a power signal to the power spine 315-b, and the power spine 315-b may route the power signal to each memory die of the stacked memory dies 310. As described with reference to FIGS. 2A and 2B, the power spines 205 and the rails 210 may further route the power signal within the respective die. Because the power spine 315-b and the power pillar 320 are not coplanar, the power spine 315-b (e.g., the power pillars of the power spine 315-b) and the power pillar 320 may be “offset” in nature.

Additionally, or alternatively, the associated memory device may include one or more thermal pillars 325. In some instances, a thermal pillar 325 may be structurally similar to a power pillar 320, but may not extend through the interface die 305 or a respective stacked die 310. That is, a power signal may not be routed through a thermal pillar 325, and the thermal pillars 325 may instead receive the power signal and store (e.g., temporarily store) extra capacitance for the memory device. In some examples, the thermal pillars 325 may also act as a thermal barrier between respective stacked dies 310 and between the stacked dies 310 and the interface die 305. Implementing the offset pillars described herein may increase the quantity of power connection points of a memory device and increase the overall performance of the associated memory system without increasing its size.

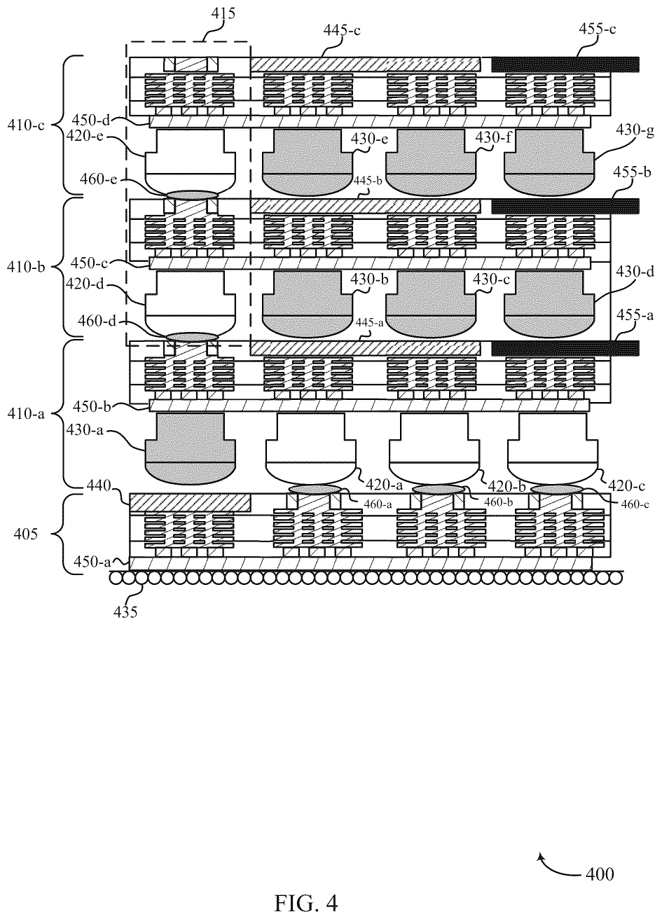

FIG. 4 shows an example of an architecture 400 that supports offset pillars for a memory system in accordance with examples as disclosed herein. The architecture 400 may illustrate a side view of aspects of a stacked memory device. In some instances, the architecture 400 may illustrate an interface die 405 and one or more stacked dies 410 above (e.g., on top of) the interface die 405. For example, the architecture 400 may illustrate a first memory die 410-a, a second memory die 410-b, and a third memory die 410-c. The interface die 305 may be coupled with a power source 435. In some instances, the interface die 405 and the stacked dies 410 may include or otherwise be coupled with one or more power spines 415, one or more power pillars 420, and one or more thermal pillars 430. In some instances, the power spines 415 and power pillars 420 may route power from the interface die 405 to each of the stacked dies 410. Additionally, or alternatively, the thermal pillars 430 may provide insulative benefits to the interface die 405, the stacked dies 410, or both. Implementing the offset pillars described herein may increase the quantity of power connection points of a memory device and increase the overall performance of the associated memory system without increasing its size.

In some instances, the interface die 405 may be coupled with a power source 435. The power source 435 may provide power to the interface die 405 and each of the stacked dies 410. In some examples, the power source 435 may include one or more bumps (e.g., one or more power bumps) or one or more micro bumps (e.g., one or more micro power bumps). The interface die 405 may include a wiring structure 450-a that is coupled with the power source 435. In some instances, the wiring structure 450-a may be or may be referred to as a voltage rail or any structure configured to carry (e.g., route) a power signal.

Additionally, or alternatively, the interface die 405 may include circuitry 440 for accessing one or more of the stacked dies 410. In some examples, the circuitry 440 may include CMOS circuitry (e.g., CMOS diffusion circuitry). The circuitry 440 may be located on a top side (e.g., an upper side) of the interface die 405 and may be aligned (e.g., vertically aligned) with the power spine 415.

The first memory die 410-a may include a thermal pillar 430-a and one or more power pillars 420. For example, the memory die 410-a may include a power pillar 420-a, a power pillar 420-b, and a power pillar 420-c. The power pillar 420-a, the power pillar 420-b, and the power pillar 420-c may be aligned in a horizontal direction and may be coupled with the power source 435 via the interface die 405 and may be configured to route a power signal to at least the first memory die 410-a. In some examples, the power pillar 420-a, the power pillar 420-b, and the power pillar 420-c may each be associated with a respective via 460. That is, each via 460 may be a hole or a location at which the respective power pillars 420 can receive a power signal from the interface die 405. For example, because the power pillars 420 may be conductive in nature, they may be configured to route a power signal received from the power source 435. In some instances, the via 460-a may be associated with (e.g., generally aligned with) the power pillar 420-a, the via 460-b may be associated with (e.g., generally aligned with) the power pillar 420-b, and the via 460.

In some instances, the first memory die 410-a may include a wiring structure 450-b that is coupled with the power pillar 420-a, the power pillar 420-b, and the power pillar 420-c. The wiring structure 450-b may receive a power signal from the power source 435 (e.g., via the power pillars 420 of the first memory die 410-a) and provide (e.g., route) the power signal to components of the first memory die 410-a. For example, the first memory die 410-a may include a memory array 445-a that is generally aligned (e.g., in a vertical direction) with at least the power pillar 420-a and the power pillar 420-b. In some instances, the wiring structure 450-b may be or may be referred to as a voltage rail or any structure configured to carry (e.g., route) a power signal.

The first memory die 410-a may include a thermal pillar 430-a. The thermal pillar 430-a may be coupled with the wiring structure 450-b but may be decoupled from the interface die 405. That is, the thermal pillar 430-a may receive a power signal from the wiring structure 450-b and may store a capacitance associated with the power signal for use by the memory array 445-a or another component of the first memory die 410-a.

The second memory die 410-b may include a power pillar 420-d (that is offset from the power pillar 420-a) and one or more thermal pillars 430. For example, the memory die 410-b may include a thermal pillar 430-b, a thermal pillar 430-c, and a thermal pillar 430-d. The power pillar 420-d and the thermal pillar 430-b, the thermal pillar 430-c, and the thermal pillar 430-d may be aligned in a horizontal direction. The power pillar 420-d may be included in the power spine 415 and may be vertically aligned (e.g., above) the thermal pillar 430-a. In some instances, the power pillar 420-d may be coupled with the power source 435 via the interface die 405 and the first memory die 410-a and may be configured to route a power signal to at least the second memory die 410-b.

In some examples, the power pillar 420-d may be associated with a via 460-d. That is, the via 460-d may be a hole or a location at which the power pillar 420-d can receive a power signal from the interface die 405 and the first memory die 410-a. For example, because the power pillar 420-d may be conductive in nature, it may be configured to route a power signal received from the power source 435.

In some instances, the second memory die 410-b may include a wiring structure 450-c that is coupled with the power pillar 420-d. The wiring structure 450-c may receive a power signal from the power source 435 (e.g., via the power pillars 420 of the first memory die 410-a and the power pillar 420-d of the second memory die 410-b) and provide (e.g., route) the power signal to components of the second memory die 410-b. For example, the second memory die 410-b may include a memory array 445-b that is generally aligned (e.g., in a vertical direction) with at least the thermal pillar 430-b and the thermal pillar 430-c. In some instances, the wiring structure 450-c may be or may be referred to as a voltage rail or any structure configured to carry (e.g., route) a power signal.

The second memory die 410-b may include a thermal pillar 430-b, a thermal pillar 430-c, and a thermal pillar 430-d. The thermal pillar 430-b, the thermal pillar 430-c, and the thermal pillar 430-d may be coupled with the wiring structure 450-c but may be decoupled from the first memory die 410-a. That is, the thermal pillar 430-b, the thermal pillar 430-c, and the thermal pillar 430-d may receive a power signal from the wiring structure 450-c and may store a capacitance associated with the power signal for use by the memory array 445-b or another component of the second memory die 410-b.

The third memory die 410-c may include a power pillar 420-e and one or more thermal pillars 430. For example, the memory die 410-c may include a thermal pillar 430-e, a thermal pillar 430-f, and a thermal pillar 430-g. The power pillar 420-e and the thermal pillar 430-e, the thermal pillar 430-f, and the thermal pillar 430-g may be aligned in a horizontal direction. The power pillar 420-e may be included in the power spine 415 and may be vertically aligned (e.g., above) the thermal pillar 430-d. In some instances, the power pillar 420-c may be coupled with the power source 435 via the interface die 405, the first memory die 410-a, and the second memory die 410-b, and may be configured to route a power signal to at least the third memory die 410-c.

In some examples, the power pillar 420-e may be associated with a via 460-c. That is, the via 460-e may be a hole or a location at which the power pillar 420-e can receive a power signal from the interface die 405, the first memory die 410-a, and the second memory die 410-b. For example, because the power pillar 420-e may be conductive in nature, it may be configured to route a power signal received from the power source 435.

In some instances, the third memory die 410-c may include a wiring structure 450-d that is coupled with the power pillar 420-c. The wiring structure 450-d may receive a power signal from the power source 435 (e.g., via the power pillars 420 of the first memory die 410-a, the power pillar 420-d of the second memory die 410-b, and the power pillar 420-c of the third memory die 410-c) and provide (e.g., route) the power signal to components of the third memory die 410-C. For example, the third memory die 410-c may include a memory array 445-c that is generally aligned (e.g., in a vertical direction) with at least the thermal pillar 430-e and the thermal pillar 430-f. In some instances, the wiring structure 450-d may be or may be referred to as a voltage rail or any structure configured to carry (e.g., route) a power signal.

The third memory die 410-c may include a thermal pillar 430-e, a thermal pillar 430-f, and a thermal pillar 430-g. The thermal pillar 430-e, the thermal pillar 430-f, and the thermal pillar 430-g may be coupled with the wiring structure 450-d but may be decoupled from the second memory die 410-b. That is, the thermal pillar 430-e, the thermal pillar 430-f, and the thermal pillar 430-g may receive a power signal from the wiring structure 450-d and may store a capacitance associated with the power signal for use by the memory array 445-c or another component of the third memory die 410-c.

In some instances, each of the stacked dies 410 may include an area (or areas) in which vias 460 are unable to exist. For example, the area may be referred to as a keep-out-zone (KOZ) 455. Due to manufacturing constraints, product specifications, or both, the KOZ 455 cannot include vias 460, and thus cannot include thermal pillars 420. However, the interface die 405 may not include a KOZ 455, or may include a KOZ 455 that is relatively smaller than or located in a different location than the KOZs of the stacked dies 410. Accordingly, the interface die 405 may include TSVs under the KOZs 455 of the stacked dies 410. Accordingly, this may allow for additional power pillars (e.g., the power pillar 420-a, the power pillar 420-b, and the power pillar 420-c) to exist, thus increasing the quantity of connection points to the power source 435 without increasing the size of the associated memory device.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 1: An apparatus, including: an interface die; a first memory die coupled with the interface die, the first memory die including: a plurality of first conductive pillars that includes a set of first power pillars coupled with the interface die and a first thermal pillar decoupled from the interface die; and a first wiring structure configured to electrically couple with the set of first power pillars and the first thermal pillar; and a second memory die coupled with the first memory die, the second memory die including: a plurality of second conductive pillars that includes a second power pillar vertically aligned with the first thermal pillar and connected to the first wiring structure, and a set of second thermal pillars that are each vertically aligned with a respective power pillar of the set of first power pillars and decoupled from the first memory die; and a second wiring structure configured to electrically couple with the second power pillar and the set of second thermal pillars.

Aspect 2: The apparatus of aspect 1, further including: a third memory die coupled with the second memory die, the third memory die including: a plurality of third conductive pillars that includes a third power pillar vertically aligned with the second power pillar and connected to the second wiring structure, and a set of third thermal pillars that are each vertically aligned with a respective thermal pillar of the set of second thermal pillars and decoupled from the second memory die; and a third wiring structure configured to electrically connect the third power pillar and the set of third thermal pillars.

Aspect 3: The apparatus of any of aspects 1 through 2, where the first memory die includes a first memory bank and the second memory die includes a second memory bank that is vertically aligned with the first memory bank.

Aspect 4: The apparatus of any of aspects 1 through 3, where the interface die includes circuitry that is vertically aligned with the first thermal pillar.

Aspect 5: The apparatus of any of aspects 1 through 4, further including: a set of first vias extending through the interface die and vertically aligned with the set of first power pillars, where a power signal is configured to be routed from one or more power bumps coupled with the interface die to the set of first power pillars through each via of the set of first vias; and a second via extending through the first memory die and vertically aligned with the second power pillar, where the power signal is configured to be routed from the one or more power bumps coupled with the interface die to the second power pillar through the second via.

Aspect 6: The apparatus of any of aspects 1 through 5, further including: a power rail located at an upper surface of the first memory die, where the set of first power pillars is configured to route a second power signal from the power rail to the second wiring structure.

Aspect 7: The apparatus of any of aspects 1 through 6, where a second thermal pillar of the set of second thermal pillars is adjacent to the second power pillar.

Aspect 8: The apparatus of any of aspects 1 through 7, where a distance between a third power pillar of the set of first power pillars a first edge of the first memory die is less than a threshold value.

Aspect 9: The apparatus of any of aspects 1 through 8, where: the second power pillar is located in a first vertical plane; and a first power pillar of the set of first power pillars is located in a second vertical plane, the first vertical plane including a greater quantity of power pillars than the second vertical plane.

Aspect 10: The apparatus of aspect 9, where: the first thermal pillar is located in the first vertical plane; and a second thermal pillar of the set of second thermal pillars is located in the second vertical plane, the second vertical plane including a greater quantity of thermal pillars than the first vertical plane.

Aspect 11: The apparatus of any of aspects 1 through 10, further including: a plurality of power bumps coupled with the interface die.

Aspect 12: The apparatus of any of aspects 1 through 11, where the first thermal pillar is below the second power pillar.

Aspect 13: The apparatus of any of aspects 1 through 12, where the plurality of first conductive pillars extend between the interface die and the first memory die.

An apparatus is described. The following provides an overview of aspects of the apparatus as described herein:

Aspect 14: An apparatus, including: a plurality of stacked memory dies, where each memory die of the plurality of stacked memory dies includes a respective power rail; a first power spine coupled with each memory die of the plurality of stacked memory dies, where the first power spine is positioned in a first plane, and where the first power spine is configured to route a first power signal between each respective power rail of the plurality of stacked memory dies; a second power spine coupled with a subset of the plurality of stacked memory dies, where the second power spine is positioned in a second plane, and where the second power spine is configured to route the first power signal between the respective power rail of each memory die of the subset of the plurality of stacked memory dies; a first plurality of power pillars coupled with a first memory die of the plurality of stacked memory dies and offset from the first power spine and the second power spine, where each power pillar of the first plurality of power pillars is configured to route the first power signal between a first power rail of a first memory die and the second power spine; and a first thermal pillar coupled with the first power rail of the first memory die of the plurality of stacked memory dies, where the first thermal pillar is positioned in the second plane.

Aspect 15: The apparatus of aspect 14, further including: a first via extending through the first memory die, where the first power spine is configured to route the first power signal from the first power rail to a second power rail of a second memory die of the plurality of stacked memory dies through the first via; a second via extending through the second memory die, where the first power spine is configured to route the first power signal from the second power rail to a third power rail of a third memory die of the plurality of stacked memory dies through the second via; and a third via extending through the second memory die, where the second power spine is configured to route the first power signal from the second power rail to the third power rail through the third via.

Aspect 16: The apparatus of aspect 15, further including: a plurality of fourth vias extending through each of the first plurality of power pillars coupled with the first memory die, where the second power spine is configured to route the first power signal from the first power rail to the third power rail through the plurality of fourth vias.

Aspect 17: The apparatus of any of aspects 14 through 16, further including: a fourth power rail located at an upper surface of the first memory die, where the first power spine is configured to route a second power signal from the fourth power rail to a second power rail of a second memory die of the plurality of stacked memory dies.

Aspect 18: The apparatus of aspect 17, where a second thermal pillar of the plurality of thermal pillars is adjacent to a first power pillar of the second power spine.

Aspect 19: The apparatus of aspect 18, where the first power pillar of the second power spine is offset from a first power pillar of the first plurality of power pillars in a horizontal direction.

Aspect 20: The apparatus of any of aspects 18 through 19, where: the first memory die includes circuitry located below the second power spine in a vertical direction; and a second memory die of the plurality of stacked memory dies includes an array of memory cells located below the second thermal pillar in a vertical direction.

Aspect 21: The apparatus of any of aspects 14 through 20, further including: a plurality of thermal pillars coupled with a second memory die of the plurality of stacked memory dies, where each thermal pillar of the plurality of thermal pillars is located above a respective power pillar of the first plurality of power pillars.

Aspect 22: The apparatus of any of aspects 14 through 21, where a distance between a second power pillar of the first plurality of power pillars and a first edge of the first memory die is less than a threshold value.

Aspect 23: The apparatus of any of aspects 14 through 22, where: the first power spine includes a second plurality of power pillars, each power pillar of the second plurality of power pillars located between a respective memory die of the plurality of stacked memory dies; and the second power spine includes a third plurality of power pillars, each power pillar of the third plurality of power pillars located between a respective memory die of the subset of the plurality of stacked memory dies, where the second plurality of power pillars includes a greater quantity of power pillars than the third plurality of power pillars.

Aspect 24: The apparatus of any of aspects 14 through 23, further including: a plurality of power bumps, where the first power rail is coupled with the plurality of power bumps.

Aspect 25: The apparatus of any of aspects 14 through 24, where the first thermal pillar is adjacent to a first power pillar of the first power spine.

Aspect 26: The apparatus of any of aspects 14 through 25, where the first thermal pillar is below a second power pillar of the second power spine.

Aspect 27: The apparatus of any of aspects 14 through 26, where the first memory die includes an interface die.

Aspect 28: The apparatus of aspect 27, where the first plurality of power pillars are located between the interface die and the first memory die of the plurality of stacked memory dies.

Aspect 29: The apparatus of any of aspects 14 through 28, where a first power pillar of the first plurality of power pillars is adjacent to the first thermal pillar.

An apparatus is described. The following provides an overview of aspects of the apparatus as described herein:

Aspect 30: An apparatus, including: an interface die; a first memory die coupled with the interface die, the first memory die including: a plurality of first conductive pillars that includes a set of first power pillars coupled with the interface die and a first thermal pillar decoupled from the interface die; and a first wiring structure configured to electrically couple with the set of first power pillars and the first thermal pillar; a second memory die coupled with the first memory die, the second memory die including: a plurality of second conductive pillars that includes a second power pillar vertically aligned with the first thermal pillar and connected to the first wiring structure, and a set of second thermal pillars that are each vertically aligned with a respective power pillar of the set of first power pillars and decoupled from the first memory die; and a second wiring structure configured to electrically couple with the second power pillar and the set of second thermal pillars; and a third memory die coupled with the second memory die, the third memory die including: a plurality of third conductive pillars that includes a third power pillar vertically aligned with the second power pillar and connected to the second wiring structure, and a set of third thermal pillars that are each vertically aligned with a respective thermal pillar of the set of second thermal pillars and decoupled from the second memory die; and a third wiring structure configured to electrically connect the third power pillar and the set of third thermal pillars, where the first memory die includes a first memory bank, the second memory die includes a second memory bank that is vertically aligned with the first memory bank, and the third memory die includes a third memory bank that is vertically aligned with the second memory bank, and where the interface die includes circuitry that is vertically aligned with the first thermal pillar.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorous, boron, or arsenic.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
an interface die;
a first memory die coupled with the interface die, the first memory die comprising:
a plurality of first conductive pillars that includes a set of first power pillars coupled with the interface die and a first thermal pillar decoupled from the interface die; and
a first wiring structure configured to electrically couple with the set of first power pillars and the first thermal pillar; and
a second memory die coupled with the first memory die, the second memory die comprising:
a plurality of second conductive pillars that includes a second power pillar vertically aligned with the first thermal pillar and connected to the first wiring structure, and a set of second thermal pillars that are each vertically aligned with a respective power pillar of the set of first power pillars and decoupled from the first memory die; and
a second wiring structure configured to electrically couple with the second power pillar and the set of second thermal pillars.

2. The apparatus of claim 1, further comprising:
a third memory die coupled with the second memory die, the third memory die comprising:
a plurality of third conductive pillars that includes a third power pillar vertically aligned with the second power pillar and connected to the second wiring structure, and a set of third thermal pillars that are each vertically aligned with a respective thermal pillar of the set of second thermal pillars and decoupled from the second memory die; and
a third wiring structure configured to electrically connect the third power pillar and the set of third thermal pillars.

3. The apparatus of claim 1, wherein the first memory die comprises a first memory bank and the second memory die comprises a second memory bank that is vertically aligned with the first memory bank.

4. The apparatus of claim 1, wherein the interface die comprises circuitry that is vertically aligned with the first thermal pillar.

5. The apparatus of claim 1, further comprising:
a set of first vias extending through the interface die and vertically aligned with the set of first power pillars, wherein a power signal is configured to be routed from one or more power bumps coupled with the interface die to the set of first power pillars through each via of the set of first vias; and
a second via extending through the first memory die and vertically aligned with the second power pillar, wherein the power signal is configured to be routed from the one or more power bumps coupled with the interface die to the second power pillar through the second via.

6. The apparatus of claim 1, further comprising:
a power rail located at an upper surface of the first memory die, wherein the set of first power pillars is configured to route a second power signal from the power rail to the second wiring structure.

7. The apparatus of claim 1, wherein a second thermal pillar of the set of second thermal pillars is adjacent to the second power pillar.

8. The apparatus of claim 1, wherein a distance between a third power pillar of the set of first power pillars a first edge of the first memory die is less than a threshold value.

9. The apparatus of claim 1, wherein:
the second power pillar is located in a first vertical plane; and
a first power pillar of the set of first power pillars is located in a second vertical plane, the first vertical plane comprising a greater quantity of power pillars than the second vertical plane.

10. The apparatus of claim 9, wherein:
the first thermal pillar is located in the first vertical plane; and
a second thermal pillar of the set of second thermal pillars is located in the second vertical plane, the second vertical plane comprising a greater quantity of thermal pillars than the first vertical plane.

11. The apparatus of claim 1, further comprising:
a plurality of power bumps coupled with the interface die.

12. The apparatus of claim 1, wherein the first thermal pillar is below the second power pillar.

13. The apparatus of claim 1, wherein the plurality of first conductive pillars extend between the interface die and the first memory die.

14. An apparatus, comprising:
a plurality of stacked memory dies, wherein each memory die of the plurality of stacked memory dies comprises a respective power rail;
a first power spine coupled with each memory die of the plurality of stacked memory dies, wherein the first power spine is positioned in a first plane, and wherein the first power spine is configured to route a first power signal between each respective power rail of the plurality of stacked memory dies;
a second power spine coupled with a subset of the plurality of stacked memory dies, wherein the second power spine is positioned in a second plane, and wherein the second power spine is configured to route the first power signal between the respective power rail of each memory die of the subset of the plurality of stacked memory dies;
a first plurality of power pillars coupled with a first memory die of the plurality of stacked memory dies and offset from the first power spine and the second power spine, wherein each power pillar of the first plurality of power pillars is configured to route the first power signal between a first power rail of a first memory die and the second power spine; and
a first thermal pillar coupled with the first power rail of the first memory die of the plurality of stacked memory dies, wherein the first thermal pillar is positioned in the second plane.

15. The apparatus of claim 14, further comprising:
a first via extending through the first memory die, wherein the first power spine is configured to route the first power signal from the first power rail to a second power rail of a second memory die of the plurality of stacked memory dies through the first via;
a second via extending through the second memory die, wherein the first power spine is configured to route the first power signal from the second power rail to a third power rail of a third memory die of the plurality of stacked memory dies through the second via; and
a third via extending through the second memory die, wherein the second power spine is configured to route the first power signal from the second power rail to the third power rail through the third via.

16. The apparatus of claim 15, further comprising:
a plurality of fourth vias extending through each of the first plurality of power pillars coupled with the first memory die, wherein the second power spine is configured to route the first power signal from the first power rail to the third power rail through the plurality of fourth vias.

17. The apparatus of claim 14, further comprising:
a fourth power rail located at an upper surface of the first memory die, wherein the first power spine is configured to route a second power signal from the fourth power rail to a second power rail of a second memory die of the plurality of stacked memory dies.

18. The apparatus of claim 17, wherein a second thermal pillar of the plurality of thermal pillars is adjacent to a first power pillar of the second power spine.

19. The apparatus of claim 18, wherein the first power pillar of the second power spine is offset from a first power pillar of the first plurality of power pillars in a horizontal direction.

20. An apparatus, comprising:
an interface die;
a first memory die coupled with the interface die, the first memory die comprising:
a plurality of first conductive pillars that includes a set of first power pillars coupled with the interface die and a first thermal pillar decoupled from the interface die; and
a first wiring structure configured to electrically couple with the set of first power pillars and the first thermal pillar;
a second memory die coupled with the first memory die, the second memory die comprising:
a plurality of second conductive pillars that includes a second power pillar vertically aligned with the first thermal pillar and connected to the first wiring structure, and a set of second thermal pillars that are each vertically aligned with a respective power pillar of the set of first power pillars and decoupled from the first memory die; and
a second wiring structure configured to electrically couple with the second power pillar and the set of second thermal pillars; and
a third memory die coupled with the second memory die, the third memory die comprising:
a plurality of third conductive pillars that includes a third power pillar vertically aligned with the second power pillar and connected to the second wiring structure, and a set of third thermal pillars that are each vertically aligned with a respective thermal pillar of the set of second thermal pillars and decoupled from the second memory die; and
a third wiring structure configured to electrically connect the third power pillar and the set of third thermal pillars, wherein the first memory die comprises a first memory bank, the second memory die comprises a second memory bank that is vertically aligned with the first memory bank, and the third memory die comprises a third memory bank that is vertically aligned with the second memory bank, and wherein the interface die comprises circuitry that is vertically aligned with the first thermal pillar.
